(19) United States
(12) Patent Application Publication
(10) Pub. No.: US 2023/0397349 A1
(43) Pub. Date: Dec. 7, 2023

(54) HMD DEVICE AND COUNTERWEIGHT MEMBER TO BE ARRANGED ON A CARRIER DEVICE OF SUCH HMD DEVICE

(71) Applicant: BHS Technologies GmbH, Innsbruck (AT)

(72) Inventors: Mark CAPELLI, Innsbruck (AT); Michael SCHMID-SANTEK, Götzens (AT)

(73) Assignee: BHS Technologies GmbH, Innsbruck (AT)

(21) Appl. No.: 18/205,540

(22) Filed: Jun. 4, 2023

(30) Foreign Application Priority Data
Jun. 3, 2022 (DE) 20 2022 103 168.1

(51) Int. Cl. H05K 5/02

(52) U.S. Cl. CPC H05K 5/0217

(57) ABSTRACT

The present invention relates to a HMD device (1), comprising:
at least one display device (10) for displaying a captured image,
a carrier device (20) to which the at least one display device (10) is attached and having at least one attachment portion for attachment to a head of a user, and at least one counterweight member (21) via which a counterweight force against the weight force of the at least one display device is applicable, wherein
the at least one counterweight member (21) is arranged on the carrier device (20) such that the counterweight torque caused by the weight force of the counterweight member (21) counteracts the display device torque caused by the weight force of the display device (10).

### RELATED APPLICATION

This application claims the benefit of priority of Germany Patent Application No. 20 2022 103 168.1 filed on Jun. 3, 2022, the contents of which are incorporated herein by reference in their entirety.

### FIELD AND BACKGROUND OF THE INVENTION

The present invention relates to HMD device as well as a counterweight member to be arranged on a carrier device of such HMD device.

HMD devices or head-mounted display devices, respectively, are often used to display images directly in the user's field of view without the user having to look at a stationary monitor or the like. Especially in medical applications, the accuracy of the image display, but also of the image perception by the user, such as a surgeon, is crucial for the precise performance of a medical procedure. In addition, there are requirements for wearing comfort, so that the user is not impaired, or is impaired as little as possible, by wearing the HMD device, especially during long medical interventions.

For displaying corresponding images, HMD devices usually comprise a carrier device which is worn by a user on the head and to which a display device is attached in the area of the user's eyes. Due to the weight of the display device, the center of gravity of the HMD device is shifted from a user's spine toward the eyes. This causes a torque to act from the eyes toward a user's chin, and thus on the neck, when the HMD device is worn. This can significantly affect wearing comfort or ergonomics, respectively.

In addition, if the carrier device is not properly secured to the head, the torque can cause the HMD device to tilt, preventing the display device from being maintained in the predetermined position relative to the eyes and possibly causing it to fall. This may compromise safety during a medical procedure. On the other hand, if the carrier device is tightened more on a user's head to prevent tilting of the HMD device, this again has a further detrimental effect on wearing comfort.

In view of the foregoing, it is therefore an object of the present invention to provide an HMD device that is improved over the prior art, particularly with respect to a wearing comfort and/or secure retention of a wearing position.

This object is solved by the subject-matters of the independent claims. Advantageous further developments are subject-matter of the dependent claims.

### SUMMARY OF THE INVENTION

According to the invention, a HMD device comprises at least one display device for displaying a captured image, a carrier device to which the at least one display device is attached and having at least one attachment portion for attachment to a head of a user, and at least one counterweight member via which a counterweight force against the weight force of the at least one display device is applicable. Here, the at least one counterweight member is arranged on the carrier device such that the counterweight torque caused by the weight force of the counterweight member counteracts the display device torque caused by the weight force of the display device.

The counterweight member may thus reduce or balance the display device torque applied to a user of the HMD device by the weight force of the at least one display device. For example, the carrier device may include at least one carrier rim or carrier strap that can be passed around the circumference of a user's head as an attachment portion for supporting the HMD device. According to this annular configuration of the attachment portion, the counterweight member may be arranged on a side of the ring of the attachment portion that is opposite to the side of the ring of the attachment portion on which the at least one display device is arranged. In particular, the distance between the at least one display device and the counterweight member along the circumference of the annular attachment portion may be 180° such that the center of gravity of the HMD device is substantially at the center of the cervical spine.

Preferably, the weight of the at least one counterweight member is selected such that the resulting weight force in at least one predetermined relative position counterbalances the display device torque acting by the weight force of the at least one display device with respect to the center of the cervical spine. Accordingly, the torque acting on the neck of a user may be neutralized or at least reduced.

A plurality of counterweight members may also be arrangeable or attachable to the carrier device. The effective counterweight torque may thereby be flexibly adjusted.

Regardless of the number of counterweight members, the at least one counterweight member or the plurality of counterweight members are arranged on a different side of the carrier device than the at least one display device with respect to a predetermined center of gravity to be achieved. Otherwise, the counterweight torque would not counteract the display device torque.

Provided that the relative position of the at least one display device is variable, the at least one counterweight member is adapted to a relative position of the at least one display device that is usually predominantly maintained during use. For example, the HMD device may include a display device that is pivotable into and out of a user's field of view about an axis parallel to the interpupillary distance. This HMD device may be used for minimally invasive procedures in which it is assumed that the display device is predominantly located within the user's field of view. Accordingly, the position and/or weight of the counterweight member may be adapted to the display device torque when the display device is swiveled in, i.e., when the display device is positioned in the field of view. If the display device is now swiveled out of the field of view, for example 90° upwards, the center of gravity shifts away from the counterweight, with all other conditions remaining constant, so that the ratio of the display device torque to the counterweight torque also changes. By changing the center of gravity in the direction of the at least one display device, the effect of the counterweight torque decreases relative to the display device torque. This shift in the center of gravity, however, is within a manageable range and is assumed to be a comparatively brief or infrequent condition in accordance with the foregoing disclosure. The wearing comfort is thus only temporarily affected and to a minor extent. In applications in which the display device is arranged to be predominantly swung out of the user's field of vision, the counterweight member may correspondingly be adapted conversely to the then predominantly prevailing conditions.

In an embodiment, the counterweight member is detachably connectable to the carrier device.

The counterweight member may therefore be removed from the carrier device and re-arranged, for example, for replacement with another counterweight member and/or for other adjustment of the acting counterweight torque and/or for disinfection or sterilization. The releasable connection may be formed as a screw connection and/or other form-fit and/or force-fit connection, such as via snap hooks, snap closures and the like.

In an embodiment, the counterweight member is arrangeable at different positions of the carrier device and/or in different positions relative to the carrier device.

The arrangeability of the at least one counterweight member at different positions of the carrier device thereby refers to an attachment of the at least one counterweight member to different positions along the carrier device. Alternatively or in addition, however, the counterweight member may also be arrangeable in different positions relative to the carrier device, based on an attachment position on the carrier device. For this purpose, the at least one counterweight member can be pivotable with respect to an attachment position via a joint and/or displaceable via a guide. The counterweight torque may be finely adjusted by the arrangeability of the counterweight member in different positions relative to the carrier device.

In one embodiment, the HMD device is configured to change the position of the at least one counterweight member on and/or relative to the carrier device in dependence on a movement and/or weight of the at least one display device.

Referring again by way of example to the pivotable display device described above, the acting counterweight torque may thus be adjusted relative to the carrier device in response to a change in position of the display device. For example, if the center of gravity tends to shift away from the center of the head when the display device is swiveled out of a user's field of view, the counterweight member may be moved likewise in the opposite direction to the movement of the display device to compensate for the shift in center of gravity. If two display devices, i.e., separate display devices for the respective eye, are attached to the carrier device, a compensating movement of the counterweight member may be performed in response to the respective movement of the one and/or the other display device. For example, a full compensating movement may be performed upon corresponding movement of both display devices, while the compensating movement is performed only to a correspondingly reduced extent upon movement of only one display device.

Alternatively or in addition, at least partial compensation for a shift in the center of gravity due to a change in the weight of the display device may be provided. The weight of the display device may change, for example, by attaching additional components or by replacing the display device, so that an adjustment of the counterweight torque may also then be advantageous.

Changing the position of the at least one counterweight member on and/or relative to the carrier device in dependence on a movement and/or weight of the at least one display device may be accomplished by signaling control of a drive mechanism for the at least one counterweight member. For example, the HMD device may comprise a weight sensor that detects a weight or a change in weight of the at least one display device. Likewise, a sensor may detect a movement of the at least one display device relative to the carrier device. However, in addition to directly measuring corresponding quantities, corresponding driving signals of the at least one display device that are equivalent to corresponding movement may be used to change the position of the at least one counterweight member.

In order to avoid changing the position of the counterweight member every small and/or short-term change in position and/or weight of the at least one display device, a time constraint may be taken into account for controlling the counterweight member. Accordingly, the position of the at least one counterweight member is changed, for example, only after the position and/or weight of the display device has changed over a predetermined minimum period of time. Alternatively or in addition, a change in the position of the at least one counterweight member may also be provided only when a predetermined minimum change in the at least one display device has occurred. The predetermined minimum change and/or time constraint may be adapted to the effect of the corresponding display device torque change. For example, when the weight of the at least one display device is high, a change in position of the at least one counterweight member may be already provided after a shorter time and/or with a smaller predetermined minimum change in display device position. With a lower weight of the at least one display device, a larger change tolerance may be set.

Alternatively or in addition to signaling control and thus changing of the position of the at least one counterweight member, mechanical control may also be provided. For example, the at least one display device and the at least one counterweight member may be motion-coupled such that a movement of the at least one display device causes an opposite movement of the at least one counterweight member. The opposite direction relates to a movement of the counterweight member in a direction that at least partially compensates for the change in the center of gravity caused by the movement of the display device. The movement may thereby have translational and/or rotational movement components.

In an embodiment, the weight of the counterweight member or the total weight of several counterweight members is at least 10%, in particular at least 30%, preferably at least 50%, and at most 150%, in particular at most 120%, preferably at most 90% of the at least one display device.

In particular, the weight of the counterweight member or the total weight of the counterweight members is set such that it reduces, preferably reduces to at least half, more preferably completely balances, the display device torque at least in one position of the at least one weight member and the at least one display device on or relative to the carrier device.

The weight of the counterweight member or the total weight of several counterweight members, respectively, may also be selected depending on the respective position of the corresponding counterweight member. For example, the weight of a respective counterweight member may be selected to be lower when the distance to the at least one display device becomes greater, compared to a higher weight of the counterweight member when it is arranged closer to the at least one display device. The corresponding advantageous weight distributions result from the torque equilibrium.

In one embodiment, the HDM device has a control unit arranged on the carrier device for controlling the at least one display device. The control unit is thereby arrangeable at different positions of the carrier device and/or in different positions relative to the carrier device.

By arranging the control unit on the carrier device, the weight of the control unit does not affect the weight of the at least one display device and thus the display device torque. Moreover, by arranging the control unit at or in different positions, the control unit may also be used to at least partially compensate for the display device torque. For example, the control unit may also be arranged in a region of the carrier device for this purpose so that the control unit torque due to the weight of the control unit counteracts the display device torque due to the weight of the display device. In an embodiment, the control unit may thereby constitute the counterweight member. Alternatively, however, the control unit may be arranged on the carrier device in addition to the at least one counterweight member.

The arrangeability of the control unit at different positions of the carrier device and/or in different positions relative to the carrier device may be used comparably to the corresponding arrangeability of the at least one counterweight member for adaptation to different display devices and/or a change of the relative position of the at least one display device to the carrier device.

In an embodiment, the control unit is movable along the carrier device.

This allows the control unit to be easily arranged at different positions along the carrier device. For example, the carrier device may form a guide for the control unit. Preferably, an attachment portion of the carrier device may be formed as such a guide so that no additional carrier portions need to be provided for changing the position of the control unit.

Movement of the control unit along the carrier device may be performed manually and/or by a corresponding drive. In the case of signaling movement via a drive, such as a result of operating a foot switch, other switching elements, and/or performing and recognizing gestures, the flexibility of the user of the HMD device may be increased.

In an embodiment, the control unit or another control unit is configured to change the position of the control unit on and/or relative to the carrier device in dependence on a movement and/or a weight of the at least one display device.

Comparable to changing the position of the counterweight member in response to a change in the position of the at least one display device relative to the carrier device, the position of the control unit may thus, alternatively or in addition, also be adjusted in dependence on a movement and/or a changed weight of the at least one display device. Corresponding explanations in this respect regarding the counterweight member are equally transferable to the control unit and vice versa.

Accordingly, the control unit may, for example, be mechanically motion-coupled to the at least one display device. Alternatively or in addition, the control unit or another control unit may signally control a corresponding drive for moving the control unit into a different relative position with respect to the carrier device. Insofar as the control unit, for example, specifies a control signal for changing a relative position of the at least one display device, this control signal or the corresponding trigger signal for the control signal may likewise be used for controlling a compensating movement of the control unit.

In an embodiment, the at least one attachment portion of the carrier device extends at least partially along the occiput of a user with respect to an application-appropriate use.

Thus, the carrier device may be additionally retained along the occiput of a user via the attachment portion. In an embodiment, the carrier device may have at least one annular carrier body, such as a carrier strap or carrier frame, extending radially about a head circumference with respect to an extension of the spine when the head is in an upright position. The annular carrier body thereby extends in an application-appropriate use, i.e. when the HMD device is worn properly, in a section in the head circumferential direction along the occiput, i.e. a section of the head that is set back relative to the maximum head circumference.

In an embodiment, the attachment portion is formed of at least a forehead portion extending at least partially along the frontal bone of a user and a back head portion extending at least partially along the occiput of a user. In this regard, the forehead portion and the back head portion form an angle of inclination in a vertical plane in an application-appropriate use of the HMD device.

Referring again to the exemplary annular carrier body forming the carrier device or being at least a part of the carrier device, the annular carrier body thus does not extend in a straight line around the circumference of the head, but has at least two portions inclined with respect to each other by the angle of inclination. In an application-appropriate use, the back head portion is thereby inclined downwardly relative to the forehead portion, i.e., in the direction of a torso of a user. This allows the back head portion to be comfortably guided around the occiput, while still allowing the forehead portion to be positioned sufficiently deep at the forehead of a user. In addition, the angle of inclination may also avoid the need to guide the annular carrier body over the ears of a user. In this respect, the angulation of the back head portion, in use appropriate for the application, preferably extends as viewed from the forehead only behind an ear of a user with the corresponding angle of inclination around the occiput. In addition, it should be noted that the design may be based on average anatomical values of common user groups and/or corresponding adjustment options may be provided.

In one embodiment, the angle of inclination forms an angle between 5° and 30°, in particular between 10° and 20°, and/or the angle of inclination (β) is adjustable via an adjustment mechanism (23).

The angle of inclination as such may, alternatively or in addition to the change of a start of the angle of inclination along the attachment portion, be adjustable by the adjustment mechanism. This may be used to adapt the angle of incidence to individual anatomy ratios and/or to be able to change the wearing position during longer interventions or for other reasons. The adjustment of the angle of inclination may also be used to change the position of a counterweight member attached to the back head portion, if it is moved along with a movement of the back head portion. The back head portion may be pivotably supported at the forehead portion. This may, for example, allow better adaptation to individual head shapes and/or wearing preferences of a user. The angle of inclination may contribute to placing the back head portion at the occiput. This may also prevent the carrier device from slipping forward.

The adjustment mechanism may be in the form of a set screw, slider or the like, the movement of which itself causes adjustment of the angle of inclination. Alternatively, the back head portion and the forehead portion may be interconnected by a joint, the joint being lockable and unlockable by the adjustment mechanism.

In an embodiment, the at least one counterweight member is a functional member of the HMD device.

For example, the counterweight member may be a setting mechanism, such as a set screw for a setting of the width of the annular carrier body. Accordingly, no additional components are mandatory as counterweight member.

In an embodiment, the HMD device is part of a robot-assisted visualization system, in particular for minimally invasive procedures.

The ergonomic design of the HMD device allows the user to be relieved, especially in complex applications in the field of robotic visualization systems, without having to forfeit functionalities of the HMD device in order to increase wearing comfort. In particular, in combination with an HMD device controlled via head movements, the balancing of the display device torque is advantageous, since the display device torque, which may tend to pull the head of a user downwards, makes control via precise head movements otherwise difficult.

Another aspect of the present invention relates to a counterweight member for being arranged on a carrier device of a previously described HMD device, wherein the weight of the counterweight member is variable.

By varying the weight of the counterweight member, the counterweight torque acting thereby can be adjusted. This may be accomplished alternatively or in addition to changing the relative position of the counterweight member on or to the carrier device.

In an embodiment, the counterweight member is configured as a fillable hollow body.

The fillable hollow body may, for example, be filled with a fluid and/or solids, for example beads, prior to a procedure. Alternatively or in addition, however, the counterweight member may also be variably filled with fillers during a procedure when connected to a corresponding supply line. The change in weight may also be reduced or reduced again by suction via the same or a further line. Controlled filling and/or suction may be provided via the control unit or another control unit provided elsewhere. The control may in particular be based on a control signal of a movement of the at least one display device and/or on a weight sensor signal corresponding to a weight of the at least one display device.

Alternatively or in addition to a fillable hollow body, a change in weight of the counterweight member may be accomplished by attaching and removing counterweight member components and/or additional counterweight members to or from the counterweight member.

Another aspect of the present invention relates to a counterweight member for being arranged on a carrier device of a previously described HMD device, or to a further embodiment of the previously described counterweight member, wherein the counterweight member comprises at least one magnetic portion, in particular an electromagnetic portion, for attaching the counterweight member to the carrier device.

Via the magnetic portion, the counterweight member can be attached to and removed from counterpole magnetic portions of the carrier device in a simple and flexible manner. Electromagnetic portions on the counterweight member and/or the carrier device may be used to selectively activate and deactivate the attachment capability.

The features described in the foregoing description of the HMD device are equally applicable to the counterweight member insofar as they pertain thereto. Likewise, features described with respect to the counterweight member are applicable to the HMD device, insofar as they have not already been described with respect thereto.

### BRIEF DESCRIPTION OF THE SEVERAL VIEWS OF THE DRAWINGS

In detail

FIG. 1 shows a schematic lateral view of a HMD device according to an exemplary embodiment with the display device flipped down;

FIG. 2 shows a schematic lateral view of a HMD device according to an exemplary embodiment according to FIG. 1 with the display device flipped up;

FIG. 3 shows a schematic lateral view of a HMD device according to an exemplary embodiment according to FIG. 1 to illustrate an angle of inclination; and

FIG. 4 shows a schematic lateral view of a HMD device according to an exemplary embodiment according to FIG. 2 to illustrate adjustment options.

### DESCRIPTION OF SPECIFIC EMBODIMENTS OF THE INVENTION

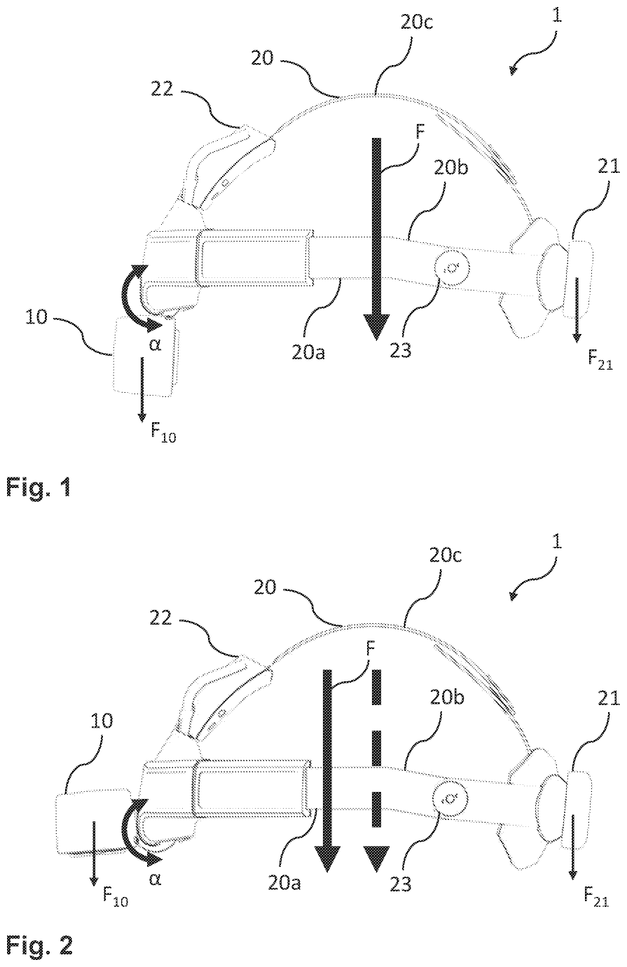

FIG. 1 shows a schematic lateral view of a HMD device 1 according to an exemplary embodiment with the display device 10 flipped down. The display device 10 is a unit with two eyepieces, whereby only one eyepiece is visible due to the lateral view. In an alternative embodiment, the HMD device 1 may also have two display devices, each comprising an eyepiece. The two display devices may each be controllable differently, so that an independent display position is made possible for a respective eye of a user.

In the present embodiment, the display device 10 is attached to a carrier device 20 via a swivel joint represented by the swivel angle α. The swivel angle α relates to a tilting of the display device 10 about an axis parallel to a connecting line of the eyes of a user. Accordingly, the display device can be pivoted into and out of the field of view of a user, wherein intermediate positions are also possible.

The carrier device 20 has an annular carrier body 20a, 20b radially surrounding a head circumference of a user with respect to an extension of the spine when the head is held upright, and an elevation carrier portion 20c. The elevation portion 20c extends arcuately from the plane formed by the annular carrier body 20a, 20b to connect two opposite points of the annular carrier body 20a, 20b. In the exemplary embodiment, the elevation portion 20c extends as a strip from a center of the forehead or frontal bone via the parietal bone toward the occiput of a user to be assumed in an application-appropriate use. The annular carrier body 20a, 20b is formed of a forehead portion 20a extending in a head circumferential direction over the frontal bone and a back head portion 20b extending in a head circumferential direction around the occiput. The forehead portion 20a, the back head portion 20b, and the elevation portion 20c respectively form attachment portions of the carrier device 20 to enable the carrier device to be held on a head of a user.

A control unit 22 is attached to the elevation portion 20c to control the display device 10. The control includes controlling the movement of the display device 10 according to the swivel angle α, for example, to swivel the display device 10 into and out of the field of view of a user, that is, to flip the display device 10 down and up. In addition, image representations on a display area of the display device 10 may be controlled by the control unit 22, such as a magnification, an image section change, a brightness, or the like. The control unit 22 is arranged here in a forehead area of a user with respect to an application-appropriate use.

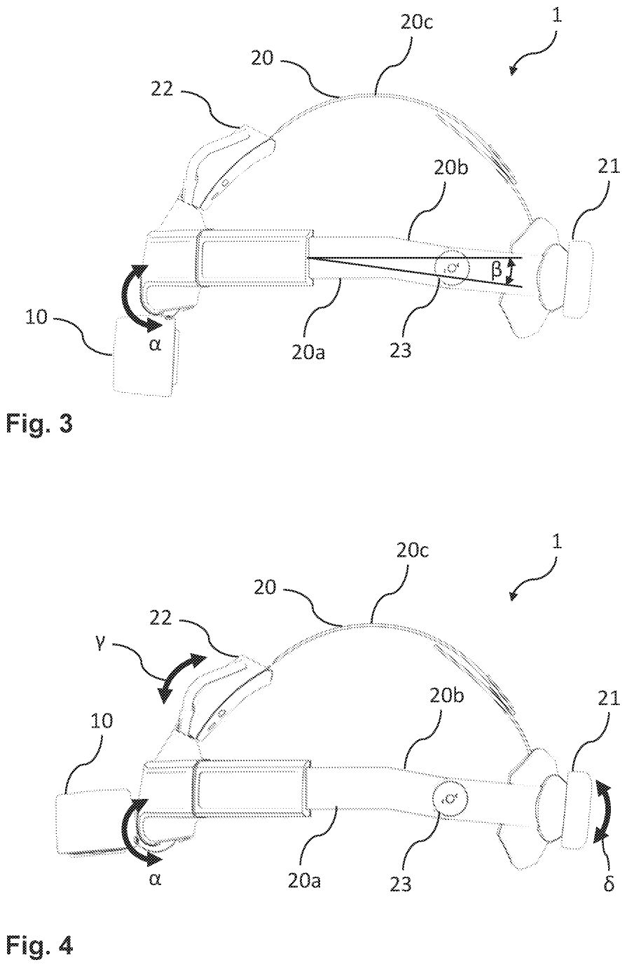

The back head portion 20b has a counterweight member 21 at a center of the occiput of a user with respect to the head circumferential direction. In this case, the counterweight member 21 is opposed to the display device 10 with respect to an extension of the spine when the head is held upright. Here, the counterweight member 21 is also formed as a width adjustment mechanism of the annular carrier body 20a, 20b. In the embodiment shown, the width adjustment mechanism or counterweight member 21, respectively, is exemplarily formed as a setting dial. In addition, the back head portion 20b has an adjustment mechanism 23 for adjusting an angle of inclination β, as will be described further with reference to FIG. 3.

Due to the weight of the display device 10, a weight force F10 of the display device 10 acts on the carrier device 20. Thereby, a display device torque is applied to the carrier device, which acts counterclockwise in the shown illustration. Since the opposite counterweight member 21 equally applies a weight force F21 of the counterweight member 21 by its weight, which results in a counterweight torque, the effect of the display device torque can be at least partially compensated. The counterweight torque acts in the opposite direction to the display device torque, i.e. clockwise in the illustration shown. The weight of the counterweight member 21 is thereby selected such that the resulting force at the center of gravity F according to the representing arrow acts substantially in a region of extension of the spine when a user holds his head upright. The region of extension of the spine is also referred to hereinafter as the reference center of gravity. Assuming that the distance of the display device 10 and the counterweight member 21 from the reference center of gravity is substantially the same, the weight of the counterweight member 21 is also substantially the same as the weight of the display device 10. Thus, when the head is held upright, the display device torque and the counterweight torque are mutually balanced. However, the reference center of gravity may also be predetermined differently depending on the predominant head posture of a user and/or changed during a wearing of the HMD device 1 depending on a head posture or for a change of the main load point. However, insofar as other components of the HMD device 1, such as, for example, the control unit 22, also have to be taken into account by a respective weight force during a torque compensation, the counterweight member 21 may also have a higher or lower weight depending on the position of these components. Consequently, the counterweight member 21 is then not only adapted to the display device 10, but to the overall torque acting beyond the reference center of gravity opposite the counterweight member 21.

FIG. 2 shows a schematic lateral view of the HMD device 1 according to FIG. 1 with the display device 10 flipped up. By tilting the display device 10 from the flipped down position by a swivel angle α of here about 80° to 90° away from the head circumference, i.e. clockwise in the illustration shown, the point of application of the weight force F10 of the display device 10 shifts to a greater distance to the reference center of gravity. The resulting force at the center of gravity F thus now acts at a point correspondingly displaced in the direction of the frontal bone. This displacement is illustrated by the dashed arrow as the previous force application point and by the continuous arrow as the displaced force application point. The weight force F21 of the counterweight member 21 is nevertheless sufficiently dimensioned to keep the displaced force application point within a tolerance range. The tolerance range here covers, for example, a range that extends radially around the reference center of gravity with respect to an extension of the spine in an upright head posture and does not extend beyond the neck of a user here.

FIG. 3 shows a schematic lateral view of the HMD device 1 according to FIG. 1 to illustrate the angle of inclination β. The angle of inclination β represents the inclination of the back head portion 20b relative to the forehead portion 20a. Starting from the straight extension of the forehead portion 20a, the back head portion 20b extends with the angle of inclination β in a direction away from the elevation portion 20c. Accordingly, the back head portion 20b is guided along the occiput in a lower course away from the parietal bone compared to a course further straight from the forehead portion 20a. This allows the carrier device 20 to be better held by way of the occiput. Via the angle of inclination β, the annular carrier body 20a, 20b may also be better guided past the ears of a user.

To adjust the angle of inclination β, the back head portion 20b has an adjustment mechanism 23. The adjustment mechanism 23 is provided on both sides of the carrier device 20, although based on the illustration, the adjustment mechanism 23 on the other side of the carrier device 20 is hidden.

FIG. 4 shows a schematic lateral view of the HMD device 1 according to FIG. 2 to illustrate adjustment possibilities. As described with respect to FIG. 2, the flipping up of the display device 10 results in a displacement of the point of application of the resulting force in the center of gravity F. If this displacement of the point of application of the force is to be counteracted or if a change of the reference center of gravity is intended for other reasons, the HMD device offers various adjustment possibilities for this.

As indicated by the double arrow as control unit motion γ, the control unit 22 is bidirectionally movable along the elevation section 20. For example, when the display device 10 is manually flipped up, the control unit can be correspondingly moved manually in a guided manner along the elevation section 20c in the direction of the parietal bone, i.e., away from the display device 10. When the display device 10 is flipped down, the control unit may be moved again in the opposite direction. The movement of the control unit 22 may also be used for individual adjustment of the torque ratios according to user preferences. The control unit 22 is further configured to pivot the display device 10 by a corresponding swivel angle α when appropriately actuated. In this regard, the control unit 22 may likewise control a drive for moving the control unit 22 so that the aforementioned manual change of the relative position of the control unit 22 along the elevation section 20c is performed automatically. In this regard, the control unit 22 may take into account a timing element and/or a minimum value of the swivel angle α so that only short-term and/or minor changes in the position of the display device 10 do not result in the control unit 22 being moved too frequently or in a manner that is not appropriate. Even though the control unit 22 may be moved here both manually and in a controlled manner, in alternative embodiments only one of the movement variants may be given, provided that a movement of the control unit 22 is intended.

Further, as indicated by the double arrow as the counterweight motion 5, the counterweight member 21 is also movable along the occiput in a direction facing to and away from the parietal bone. This may be accomplished via an articulated arrangement of the counterweight member 21 on the back head portion 20b. In principle, however, such a movement may also be performed via the adjustment mechanism 23 for changing the angle of inclination β. For example, when the display device 10 is moved to a flipped up position as shown in FIG. 4, the counterweight member 21 may be moved in the direction toward the parietal bone to increase the distance from the reference center of gravity, and vice versa. The movement of the counterweight member 21 may be performed alternatively or in addition to the movement of the control unit 22.

The invention is not limited to the embodiment described. In particular, features described with respect to the embodiment, otherwise described configurations and further developments of the invention may be combined with each other, provided that they are not reasonably mutually exclusive. Also, individual features alone may be considered independent, even if they are disclosed together with other features in one embodiment. Even if only one counterweight member is shown in the embodiment described, multiple counterweight members may be used. Moreover, the position of the at least one counterweight member relative to the carrier device is not limited to a position opposite the display device. Accordingly, it may also be provided that the at least one counterweight member 21 may be moved bidirectionally along the back head portion 20b in the head circumferential direction.

### REFERENCES

1 HMD device
10 display device
20 carrier device
20a forehead portion
20b back head portion
20c elevation carrier portion
21 counterweight member
22 control unit
23 adjustment mechanism
F force at the center of gravity
F10 weight force of the display device
F21 weight force of the counterweight member
α swivel angle (display device)
β angle of inclination
γ control unit motion
δ counterweight motion

What is claimed is:

1. A HMD device, comprising:
at least one display device for displaying a captured image,
a carrier device to which the at least one display device is attached and having at least one attachment portion for attachment to a head of a user, and
at least one counterweight member via which a counterweight force against the weight force of the at least one display device is applicable, wherein
the at least one counterweight member is arranged on the carrier device such that the counterweight torque caused by the weight force of the counterweight member counteracts the display device torque caused by the weight force of the display device.

2. The HMD device according to claim 1, wherein
the counterweight member is detachably connectable to the carrier device.

3. The HMD device according to claim 1, wherein
the counterweight member is arrangeable at different positions of the carrier device and/or in different positions relative to the carrier device.

4. The HMD device according to claim 3, wherein
the HMD device is configured to change the position of the at least one counterweight member on and/or relative to the carrier device in dependence on a movement and/or a weight of the at least one display device.

5. The HMD device according to claim 1, wherein
the weight of the counterweight member or the total weight of several counterweight members is at least 10% and at most 150% of the at least one display device.

6. The HMD device according to claim 1, wherein
the HDM device comprises a control unit being arranged on the carrier device for controlling the at least one display device, and wherein
the control unit is arrangeable at different positions of the carrier device and/or in different positions relative to the carrier device.

7. The HMD device according to claim 6, wherein
the control unit is movable along the carrier device.

8. The HMD device (1) according to claim 6, wherein
the control unit or another control unit is configured to change the position of the control unit on and/or relative to the carrier device in dependence of a movement and/or a weight of the at least one display device.

9. The HMD device according to claim 1, wherein
the at least one attachment portion of the carrier device extends at least partially along the occiput of a user with respect to an application-appropriate use.

10. The HMD device according to claim 9, wherein
the attachment portion is formed of at least a forehead portion extending at least partially along the frontal bone of a user and an back head portion extending at least partially along the occiput of a user, and wherein
the forehead portion and the back head portion form an angle of inclination in a vertical plane in an application-appropriate use of the HMD device.

11. The HMD device according to claim 10, wherein
the angle of incidence forms an angle between 5° and 30°, and/or
the angle of inclination is adjustable via an adjustment mechanism.

12. The HMD device according to claim 1, wherein
the at least one counterweight member is a functional member of the HMD device.

13. The HMD device according to claim 1, wherein
the HMD device is part of a robot-assisted visualization system.

14. A counterweight member for being arranged on a carrier device of an HMD device according to claim 1, wherein
the weight of the counterweight member is variable.

15. The counterweight member according to claim 14, wherein
the counterweight member is configured as a fillable hollow body.

16. The counterweight member according to claim 14, wherein
the counterweight member comprises at least one magnetic portion for attaching the counterweight member to the carrier device.

17. The HMD device according to claim 5, wherein
the weight of the counterweight member or the total weight of several counterweight members is at most 120% of the at least one display device.

18. The HMD device according to claim 5, wherein
the weight of the counterweight member or the total weight of several counterweight members is at most 90% of the at least one display device.

19. The HMD device according to claim 5, wherein
the weight of the counterweight member or the total weight of several counterweight members is at least 30% of the at least one display device.

20. The HMD device according to claim 17, wherein
the weight of the counterweight member or the total weight of several counterweight members is at least 30% of the at least one display device.

21. The HMD device according to claim 18, wherein
the weight of the counterweight member or the total weight of several counterweight members is at least 30% of the at least one display device.

22. The HMD device according to claim 5, wherein
the weight of the counterweight member or the total weight of several counterweight members is at least 50% of the at least one display device.

23. The HMD device according to claim 17, wherein
the weight of the counterweight member or the total weight of several counterweight members is at least 50% of the at least one display device.

24. The HMD device according to claim 18, wherein
the weight of the counterweight member or the total weight of several counterweight members is at least 50% of the at least one display device.

25. The HMD device according to claim 11, wherein
the angle of incidence forms an angle between 10° and 20°.

26. The counterweight member according to claim 16, wherein
the counterweight member the at least one magnetic portion is an electromagnetic portion for attaching the counterweight member to the carrier device.

27. A counterweight member for being arranged on a carrier device of an HMD device according to claim 1, wherein the counterweight member comprises at least one magnetic portion for attaching the counterweight member to the carrier device.
